(19) United States
(12) Patent Application Publication
(10) Pub. No.: US 2026/0352157 A1
(43) Pub. Date: Nov. 5, 2026

(54) AMPLIFIER CONTROL CIRCUIT WITH ERROR CURRENT COMPENSATION

(71) Applicant: TEXAS INSTRUMENTS INCORPORATED, Dallas, TX (US)

(72) Inventors: Tyler James Archer, Vail, AZ (US); Bharath Karthik Vasan, Tucson, AZ (US); Purnendu Bhattaru, Bangalore (IN)

(73) Assignee: Texas Instruments Incorporated, Dallas, TX (US)

(21) Appl. No.: 19/634,549

(22) Filed: Mar. 31, 2026

Related U.S. Application Data
(60) Provisional application No. 63/797,270, filed on Apr. 30, 2025.

(51) Int. Cl. H03F 1/02; H03F 3/04

(52) U.S. Cl. CPC H03F 1/0205; H03F 3/04

(57) ABSTRACT

A circuit includes a first transistor, a second transistor, a third transistor, and a fourth transistor. The first transistor has a collector, an emitter, and a base. The second transistor has a collector coupled to the emitter of the first transistor, an emitter coupled to the collector of the first transistor, and a base. The third transistor has a first terminal coupled to the base of the first transistor and a second terminal coupled to the collector of the first transistor and to the emitter of the second transistor. The fourth transistor has a first terminal coupled to the base of the second transistor and a second terminal coupled to the collector of the second transistor and to the emitter of the first transistor.

### CROSS-REFERENCE TO RELATED APPLICATIONS

This application claims priority to U.S. Provisional Application No. 63/797,270 filed Apr. 30, 2025, which is hereby incorporated by reference in its entirety.

### BACKGROUND

Amplifier circuits are used in a variety of electronic systems to amplify input signals, for example, input signals from one or more sensor circuits, to facilitate further processing in the system. Some amplifier circuits may include one or more gain stages between an input stage and an output stage to increase the open-loop gain of the amplifier circuit. However, trade-offs to achieve the increased gain may include decreased amplifier bandwidth and slew rate of the amplifier circuit and/or increased size, power consumption, and design complexity of the amplifier circuit.

### SUMMARY

In one example, a circuit includes a first transistor, a second transistor, a third transistor, and a fourth transistor. The first transistor has a collector, an emitter, and a base. The second transistor has a collector coupled to the emitter of the first transistor, an emitter coupled to the collector of the first transistor, and a base. The third transistor has a first terminal coupled to the base of the first transistor and a second terminal coupled to the collector of the first transistor and to the emitter of the second transistor. The fourth transistor has a first terminal coupled to the base of the second transistor and a second terminal coupled to the collector of the second transistor and to the emitter of the first transistor.

In another example, a circuit includes a first transistor, a second transistor, a third transistor, and a fourth transistor. The first transistor has a collector, an emitter, and a base. The second transistor has a collector coupled to the emitter of the first transistor, an emitter coupled to the collector of the first transistor, and a base. The third transistor has a first terminal coupled to the base of the first transistor and a second terminal coupled to the emitter of the first transistor and to the collector of the second transistor. The fourth transistor has a first terminal coupled to the base of the second transistor and a second terminal coupled to the emitter of the second transistor and to the collector of the first transistor.

In yet another example, a circuit includes control circuitry and error current compensation circuitry. The control circuitry includes a first transistor coupled in parallel with a second transistor, where the first and second transistors have respective control terminals. The first transistor produces a first current based on an input voltage, and the second transistor produces a second current based on the input voltage. The error current compensation circuitry includes a third transistor having a first terminal coupled to the control terminal of the first transistor and a second terminal coupled to first terminals of the first and second transistors, where the third transistor redirects a third current generated at the control terminal of the first transistor. The error current compensation circuitry also includes a fourth transistor having a first terminal coupled to the control terminal of the second transistor and a second terminal coupled to second terminals of the first and second transistors, where the fourth transistor redirects a fourth current generated at the control terminal of the second transistor.

### BRIEF DESCRIPTION OF THE DRAWINGS

FIG. 1 is a circuit schematic illustrating an example amplifier circuit including a control circuit with error current compensation.

FIG. 2 is a signal diagram illustrating examples of open-loop gain (A_{OL}) for an amplifier circuit with different control transistor current gains.

FIG. 3 is a signal diagram illustrating small signal A_{OL} gain for an amplifier circuit without error current compensation and an amplifier circuit with error current compensation.

FIG. 4 is a circuit schematic illustrating another example amplifier circuit including a control circuit with error current compensation.

FIG. 5 is a circuit schematic illustrating another example amplifier circuit including a control circuit with error current compensation.

FIG. 6 is a circuit schematic illustrating another example amplifier circuit including a control circuit with error current compensation.

FIG. 7 is a circuit schematic illustrating another example amplifier circuit including a control circuit with error current compensation.

### DETAILED DESCRIPTION

This description relates to amplifier circuits. More particularly, circuitry described herein relates to a control circuit for an amplifier circuit, also referred to herein as an amplifier control circuit, with error current compensation.

A two-stage amplifier circuit design includes an input stage coupled to an output stage, with the output stage including output drivers and a control circuit for the output drivers. A three-stage amplifier circuit design includes the input stage and the output stage, but also includes an intermediate stage coupled between the input stage and the output stage. Including the intermediate stage in the three-stage amplifier circuit design improves the open-loop gain of the amplifier circuit but at the cost of decreased bandwidth and slew rate, due to a slower outer compensation loop. The decreased slew rate slows down the amplifier circuit, which is at least partially compensated for by increased power consumption. Adding the intermediate gain stage can also increase the size and design complexity of the three-stage amplifier circuit design.

Examples of the described solution include a control circuit with error current compensation that can be used in an amplifier circuit, including a two-stage amplifier circuit. Including the error current compensation enables an increase in the open-loop gain of the amplifier circuit without using an intermediate gain stage. Also, two-stage amplifier circuit designs with the described error current compensation can have the increased open-loop gain over other two-stage amplifier circuit designs while having increased bandwidth and speed and decreased size, power consumption, and design complexity over some three (or more) stage amplifier circuit designs.

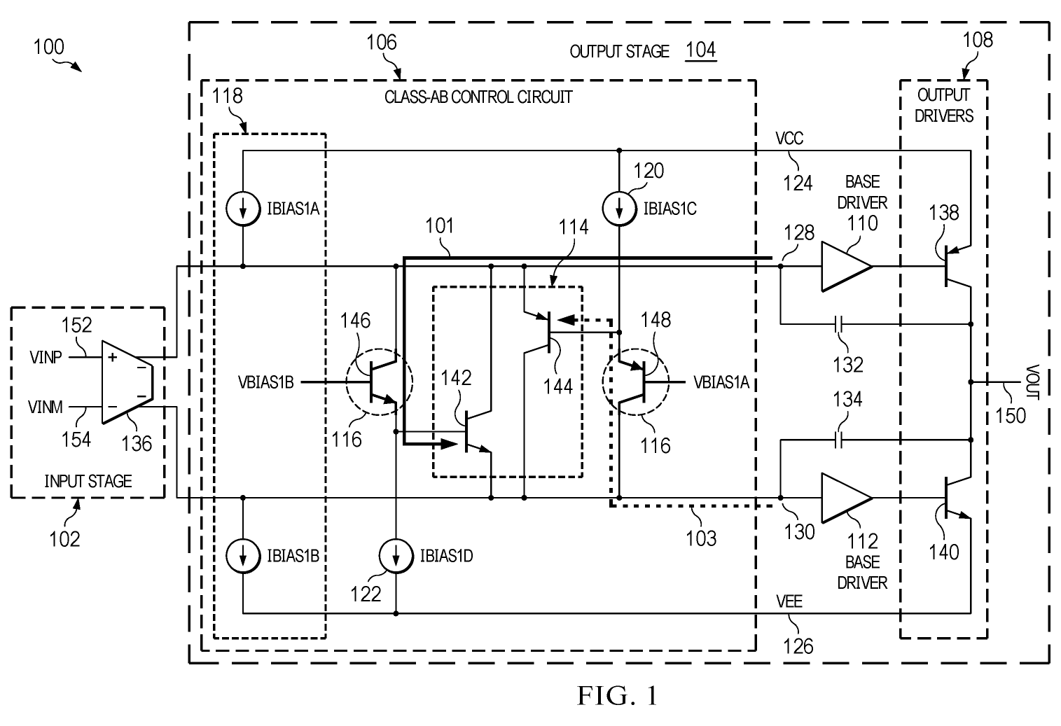

FIG. 1 is a circuit schematic illustrating an example amplifier circuit 100 including a control circuit with error current compensation. Amplifier circuit 100 includes an example input stage 102 coupled to an example output stage 104. Input stage 102 includes an example transconductance circuit 136. Output stage 104 includes an example control circuit 106, output drivers 108, a driver circuit 110, a driver circuit 112, a capacitor 132, and a capacitor 134. Driver circuits are referred to herein as base drivers when constructed to drive a base of a bipolar-junction transistor (BJT). Control circuit 106 includes example control circuitry 114, example error current compensation circuitry 116, and example current source circuitry 118, 120, and 122. Current source circuitry 118, 120 and 122 may also be referred to herein as bias current generators or current sources. Control circuitry 114 includes transistors 142 and 144, which may also be referred to herein as control transistors. Error current compensation circuitry 116 includes transistors 146 and 148, which may also be referred to herein as compensation or recirculation transistors. Output drivers 108 include transistors 138 and 140, which may also be referred to as output transistors. In example amplifier circuit 100, transistors 140, 142, and 146 are NPN BJTs, and transistors 138, 144, and 148 are PNP BJTs.

Also shown in FIG. 1, amplifier circuit 100 includes a first voltage supply terminal 124 (which may also be referred to as a voltage “rail”) at which a first supply voltage VCC is provided, a second voltage supply terminal 126 (which may also be referred to as a voltage “rail”) at which a second supply voltage VEE is provided, a first base drive node 128, a second base drive node 130, a first input terminal 152 and a second input terminal 154 at which a differential voltage (VINP - VINM) is provided, and an output terminal 150 at which an output voltage VOUT is provided. Base drive node 128 represents a logical electrical point at which terminals of multiple elements are coupled to an input terminal of base driver 110. Base drive node 130 represents a logical electrical point at which terminals of multiple elements are coupled to an input terminal of base driver 112.

In an example, a transconductance circuit includes a differential pair of transistors, for instance, a differential pair of PNP BJTs. In another example, a transconductance circuit is or includes an operational transconductance amplifier. Transconductance circuit 136 has a first (positive) input terminal coupled to input terminal 152, a second (negative) input terminal coupled to input terminal 154, a first (negative) output terminal coupled to base drive node 128, and a second (negative) output terminal coupled to base drive node 130. Current source circuitry 118 has a first terminal coupled to voltage supply terminal 124, a second terminal coupled to base drive node 128, a third terminal coupled to base drive node 130, and a fourth terminal coupled to voltage supply terminal 126. Current source circuitry 118 provides a bias current IBIAS1A and a bias current IBIAS1B.

Transistor 142 has a first terminal (collector) coupled to base drive node 128, a second terminal (emitter) coupled to base drive node 130, and a control terminal (base). Transistor 144 has a first terminal (collector) coupled to base drive node 130, a second terminal (emitter) coupled to base drive node 128, and a control terminal (base). Transistor 146 has a first terminal (collector) coupled to base drive node 128, a second terminal (emitter) coupled to the base of transistor 142, and a control terminal (base) that receives a bias voltage VBIAS1B. Transistor 148 has a first terminal (collector) coupled to base drive node 130, a second terminal (emitter) coupled to the base of transistor 144, and a control terminal (base) that receives a bias voltage VBIAS1A.

Current source circuitry 120 has a first terminal coupled to voltage supply terminal 124 and a second terminal coupled to the base of transistor 144 and to the emitter of transistor 148. Current source circuitry 122 has a first terminal coupled to voltage supply terminal 126 and a second terminal coupled to the base of transistor 142 and to the emitter of transistor 146. Current source circuitry 120 provides a bias current IBIAS1C. Current source circuitry 122 provides a bias current IBIAS1D.

Base driver 110 has an input terminal coupled to base drive node 128 and has an output terminal. Base driver 112 has an input terminal coupled to base drive node 130 and has an output terminal. Capacitor 132 has a first terminal coupled to base drive node 128 and a second terminal coupled to output terminal 150. Capacitor 134 has a first terminal coupled to base drive node 130 and a second terminal coupled to output terminal 150. Transistor 138 has a first terminal (collector) coupled to output terminal 150, a second terminal (emitter) coupled to voltage supply terminal 124, and a control terminal (base) coupled to the output terminal of base driver 110. Transistor 140 has a first terminal (collector) coupled to output terminal 150, a second terminal (emitter) coupled to voltage supply terminal 126, and a control terminal (base) coupled to the output terminal of base driver 112.

During operation, transconductance circuit 136 receives the differential input voltages VINP and VINM at input terminals 152 and 154 and generates currents at the output terminals of transconductance circuit 136. For example, the currents may include common mode currents (e.g., currents having the same polarity and the same magnitude) that are proportional to the voltage difference between VINP and VINM. In particular, transconductance circuit 136 converts the differential input voltage (VINP−VINM) into corresponding common-mode output currents that are delivered to Class-AB control circuit 106. The magnitude of the generated common-mode currents are proportional to the transconductance of transconductance circuit 136 and the differential input voltage.

In response to the common-mode currents generated by transconductance circuit 136, the conduction of transistors 142 and 144 is modulated. Namely, current in transistor 142 increases when VINP exceeds VINM, and current in transistor 144 increases when VINM exceeds VINP. Thus, the current flowing between base drive nodes 128 and 130 is steered between transistor 144 and transistor 142 in response to the common-mode currents from transconductance circuit 136. This steering of currents modulates the base-emitter voltages of transistor 144 and transistor 142, thereby modulating the voltages at base drive nodes 128 and 130, thereby controlling output transistors 138 and 140, thereby controlling VOUT.

Current source circuitry 118 establishes quiescent operating conditions for Class-AB control circuit 106. Bias current IBIAS1A flows through the upper bias branch of Class-AB control circuit 106, and bias current IBIAS1B flows through the lower bias branch. Bias currents IBIAS1A and IBIAS1B establish standing currents in the signal paths so that transistors 142 and 144 remain partially conductive in the absence of a differential input signal. Because both conduction paths remain slightly active at quiescent conditions, the control circuit operates in a Class-AB mode rather than a Class-B mode. The Class-AB operation reduces crossover distortion by maintaining a small amount of conduction in both signal paths even when the differential input signal is near zero.

Signal currents generated within Class-AB control circuit 106 (e.g., bias currents IBIAS1A and IBIAS1B modulated by the common-mode currents through control transistors 142 and 144) develop voltages at base drive nodes 128 and 130. The voltage variations at base drive nodes 128 and 130 are proportional to the common-mode currents generated by transconductance circuit 136. These voltage variations constitute base-drive signals that control base drivers 110 and 112.

Base drivers 110 and 112 buffer the voltage signals present at base drive nodes 128 and 130 to provide relatively high input impedance base voltage drive for output transistors 138 and 140, to generate relatively high amplifier open-loop gain A_{OL}. Base driver 110 receives the control voltage at base drive node 128 and generates a corresponding drive signal for transistor 138. Similarly, base driver 112 receives the control voltage at base drive node 130 and generates a corresponding drive signal for transistor 140. The high A_{OL}, is at least partially achieved through the high input impedance looking into base drivers 110 and 112 from base drive nodes 128 and 130.

Transistors 138 and 140 form a complementary push-pull topology, which together with base drivers 110 and 112 and Class-AB control circuit 106 within output stage 104, can be considered as a Monticelli-type output stage structure. When the signal at base drive node 128 causes base driver 110 to increase the base drive of transistor 138, transistor 138 conducts additional current from VCC toward output terminal 150, thereby increasing the voltage at VOUT. Conversely, when the signal at base drive node 130 causes base driver 112 to increase the base drive of transistor 140, transistor 140 conducts current from output terminal 150 toward VEE, thereby decreasing the voltage at VOUT. In this manner, the output stage produces voltage VOUT at output terminal 150 that is an amplified representation of the differential input signal (VINP-VINM) applied to input terminals 152 and 154. A Monticelli-type output stage structure can provide relatively lower quiescent current, improved large signal drive, lower cross-over distortion, increased rail-to-rail swing, and higher efficiency than some amplifier circuits without the Monticelli-type output stage structure.

Capacitors 132 and 134 provide frequency compensation and stabilization of output stage 104. In particular, capacitors 132 and 134 introduce dominant pole behavior and provide local feedback that improves amplifier 100 stability and prevents oscillation when driving capacitive loads. Capacitors 132 and 134 also assist in controlling slew rate and maintaining stable operation across a range of load conditions.

Although the described architecture provides efficient voltage amplification, a source of signal inefficiency arises due to the finite current gain (β) of transistors 142 and 144. The current gain of a BJT (β) is the ratio of the collector-emitter current (I_{CE}, signal current through the control transistor) to the base-emitter current (I_{BE}, signal loss (also referred to as an error current) at the base of the control transistor). Thus, β=(I_{CE}/I_{BE}). Ideally, the β would be infinite so that there is no signal loss at the base of the control transistor, but in reality, β is a process-technology-dependent parameter that can vary widely between processes technologies. So, for a given signal current (I_{CE}), the lower the β is, the larger the signal loss (I_{BE}) is. In many process technologies, β is about 100, leading to a loss of around 1/100 of the signal current (I_{CE}) to base current (I_{BE}) production (signal loss).

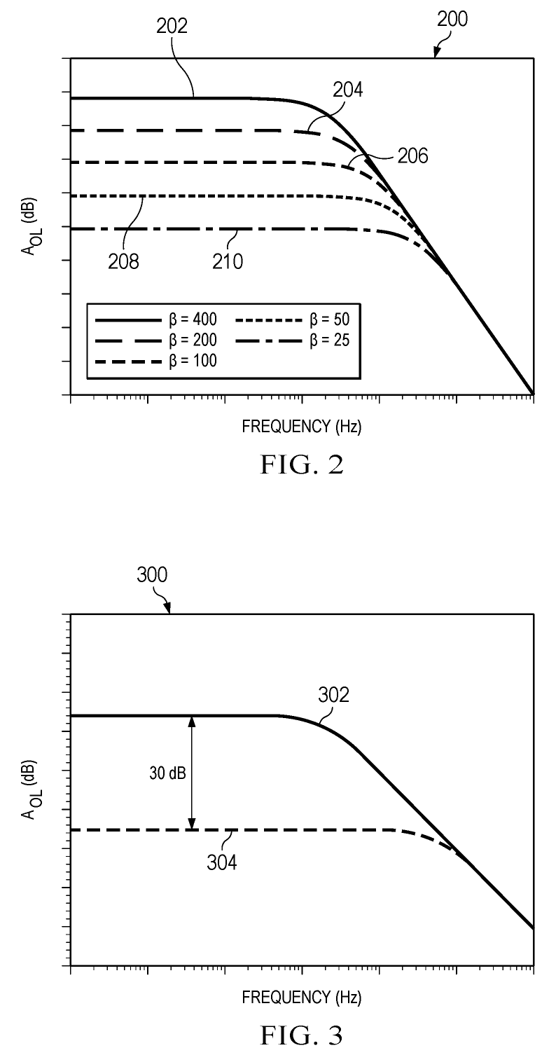

Without error current compensation circuitry 116 (including transistors 146 and 148), the diversion of signal current into the bases of transistors 142 and 144 could result in a loss of signal current that would otherwise contribute to impedance and voltage development at base drive nodes 128 and 130. As a consequence, the open-loop gain and linearity of amplifier 100 is degraded. FIG. 2 is a signal diagram 200 illustrating examples of A_{OL} for an amplifier circuit, such as amplifier circuit 100, including control transistors, e.g., 142 and 144, having different current gains, β. Waveform 202 represents the open loop gain (A_{OL})in decibels (dB) for different frequencies in Hertz (Hz) of amplifier operation for β=400. Waveform 204 represents A_{OL} for different frequencies of amplifier operation for β=200. Waveform 206 represents A_{OL} for different frequencies of amplifier operation for β=100. Waveform 208 represents A_{OL} for different frequencies of amplifier operation for β=50. Waveform 210 represents A_{OL} for different frequencies of amplifier operation for β=25. For every two times reduction in β, there is about a six dB reduction in A_{OL}.

Error current compensation circuitry 116, including transistors 146 and 148, is included within Class-AB control circuit 106 to mitigate the signal loss (error current) at the bases of transistors 142 and 144. Each of transistors 146 and 148 operate to redirect error current from the base of the control transistor 142 and 144 to which each of transistors 146 and 148 is coupled toward a base drive node. More specifically, transistor 146 is coupled so that base current drawn by transistor 142 produces a corresponding conduction current between the emitter and the collector of transistor 146. Rather than allowing this current to be dissipated locally within the control circuit 106, transistor 146 redirects the recovered current into the signal path coupled to base drive node 128, as shown by solid line 101. Similarly, transistor 148 is coupled so that base current drawn by transistor 144 causes conduction from the emitter to the collector of transistor 148, which is redirected to base drive node 130, as shown by dashed line 103. In some examples, the BJTs of error current compensation circuitry, e.g., transistors 146 and 148, are replaced with field effect transistors, e.g., metal oxide semiconductor field effect transistors (MOSFETs), or are a combination of a BJT and a MOSFET. Using one or more MOSFETs may result in smaller circuit area depending on the process technology. Using one or more MOSFETs may also allow operation on a lower supply voltage since the minimum Vds (drain-source voltage) for a MOSFET is often less than the minimum Vce (collector-emitter voltage) for a BJT.

Transistors 146 and 148 recovering and redirecting the base currents of transistors 142 and 144 back into the signal paths at the base drive nodes 128 and 130 lead to an increased open-loop gain of amplifier circuit 100. FIG. 3 is a signal diagram 300 illustrating waveforms 302 and 304. Waveform 304 shows small signal A_{OL} in dB over frequency in Hz for an amplifier circuit with two stages but without error current compensation. Waveform 302 shows small signal A_{OL} over frequency for an amplifier circuit with error current compensation, e.g., amplifier circuit 100. Some implementations of amplifier circuit 100, which include the compensation or recirculation transistors 146 and 148, have about a 30 dB greater A_{OL} as compared to the amplifier circuit without the transistors 146 and 148. Thus, a higher A_{OL} may be achieved while maintaining high bandwidth and slew rate, low power consumption, small size, and low design complexity as compared to a three-stage amplifier circuit design.

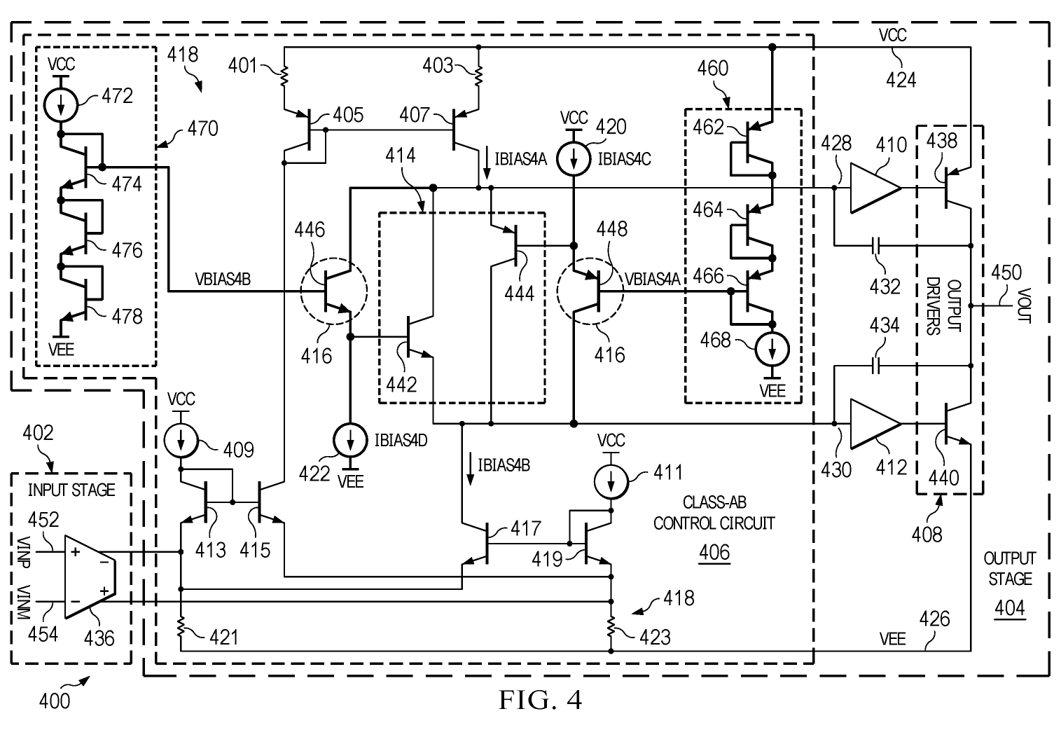

FIG. 4 is a circuit schematic illustrating another example amplifier circuit 400 including a control circuit with error current compensation. Amplifier circuit 400 includes an example input stage 402 coupled to an example output stage 404. Input stage 402 includes an example transconductance circuit 436. Output stage 404 includes an example control circuit 406, output drivers 408, a base driver 410, a base driver 412, a capacitor 432 and a capacitor 434. Control circuit 406 includes example control circuitry 414, example error current compensation circuitry 416, example current source circuitry 418, 420, and 422, and example bias voltage generators 460 and 470. Current source circuitry 418, 420, and 422 may also be referred to herein as bias current generators.

Control circuitry 414 includes transistors 442 and 444, which may also be referred to herein as control transistors. Error current compensation circuitry 416 includes transistors 446 and 448, which may also be referred to herein as compensation or recirculation transistors. Output drivers 408 include transistors 438 and 440, which may also be referred to as output transistors. Current source circuitry 418 includes diode-coupled transistor 405, transistor 407, diode-coupled transistor 413, transistor 415, transistor 417, diode-coupled transistor 419, resistors 401, 403, 421, and 423, and current source circuitry 409 and 411. Bias voltage generator 460 includes diode-coupled transistors 462, 464, and 466 and current source circuitry 468. Bias voltage generator 470 includes current source circuitry 472 and diode-coupled transistors 474, 476, and 478.

In example amplifier circuit 400, transistors 413, 415, 417, 419, 440, 442, 446, 474, 476, and 478 are NPN BJTs, and transistors 405, 407, 438, 444, 448, 462, 464, and 466 are PNP BJTs. Also, diode-coupled transistors are transistors structured with a terminal coupled to a control terminal of the transistor. In example amplifier circuit 400, diode-coupled transistors 405, 413, 419, 462, 464, 466, 474, 476, and 478 have a first terminal (collector) directly connected to a base of the transistor.

Further shown in FIG. 4 is a first voltage supply terminal 424 at which a first supply voltage VCC is provided, a second voltage supply terminal 426 at which a second supply voltage VEE is provided, a first base drive node 428, a second base drive node 430, a first input terminal 452 and a second input terminal 454 at which a differential voltage (VINP - VINM) is provided, and an output terminal 450 at which an output voltage VOUT is provided. Base drive node 428 represents a logical electrical point at which terminals of multiple elements are coupled to an input terminal of base driver 410. Base drive node 430 represents a logical electrical point at which terminals of multiple elements are coupled to an input terminal of base driver 412.

Transconductance circuit 436 has a first (positive) input coupled to input terminal 452, a second (negative) input coupled to input terminal 454, a first (positive) output, and a second (negative) output. As such, transconductance circuit 436 generates differential currents at its outputs, which have the same magnitude but different polarities. Transistors 405 and 407 are structured as a current mirror that inverts the polarity of one of these output currents so that common-mode currents that are proportional to the voltage difference between VINP and VINM are steered through control transistors 442 and 444. Current source circuitry 409, diode-coupled transistor 413, and resistor 421 are coupled in series between voltage supply terminal 424 and voltage supply terminal 426. Current source circuitry 411, diode-coupled transistor 419, and resistor 423 are coupled in series between voltage supply terminal 424 and voltage supply terminal 426. Resistor 401 and diode-coupled transistor 405 are coupled in series between voltage supply terminal 424 and a first terminal (collector) of transistor 415. A second terminal (emitter) of transistor 415 is coupled to a second terminal (emitter) of diode-coupled transistor 419, a terminal of resistor 423, and the positive output terminal of transconductance circuit 436. The control terminal (base) of transistor 415 is coupled to the collector and base of diode-coupled transistor 413 and to a terminal of current source circuitry 409. Resistor 403 and transistor 407 are coupled in series between voltage supply terminal 424 and base drive node 428. Transistor 417 has a first terminal (collector) coupled to base drive node 430 and a control terminal (base) coupled to the base and collector of diode-coupled transistor 419. Transistor 417 has a second terminal (emitter) coupled to a second terminal (emitter) of diode-coupled transistor 413, to a terminal of resistor 421, and to the negative output terminal of transconductance circuit 436. Current source circuitry 418 provides a bias current IBIAS4A at the collector of transistor 407 and a bias current IBIAS4B at the collector of transistor 417.

Transistor 442 has a first terminal (collector) coupled to base drive node 428, a second terminal (emitter) coupled to base drive node 430, and a control terminal (base). Transistor 444 has a first terminal (collector) coupled to base drive node 430, a second terminal (emitter) coupled to base drive node 428, and a control terminal (base). Transistor 446 has a first terminal (collector) coupled to base drive node 428, a second terminal (emitter) coupled to the base of transistor 442, and a control terminal (base). Transistor 448 has a first terminal (collector) coupled to base drive node 430, a second terminal (emitter) coupled to the base of transistor 444, and a control terminal (base).

Current source circuitry 420 has a first terminal coupled to voltage supply terminal 424 and a second terminal coupled to the base of transistor 444 and to the emitter of transistor 448. Current source circuitry 422 has a first terminal coupled to voltage supply terminal 426 and a second terminal coupled to the base of transistor 442 and to the emitter of transistor 446. Current source circuitry 420 provides a bias current IBIAS4C. Current source circuitry 422 provides a bias current IBIAS4D.

Current source circuitry 472 and diode-coupled transistors 474, 476, and 478 are coupled in series between voltage supply terminal 424 and voltage supply terminal 426. The base of transistor 446 is coupled to the base and collector of diode-coupled transistor 474 and to a terminal of current source circuitry 472 to receive a bias voltage VBIAS4B generated by bias voltage generator 470. Current source circuitry 468 and diode-coupled transistors 462, 464, and 466 are coupled in series between voltage supply terminal 424 and voltage supply terminal 426. The base of transistor 448 is coupled to the base and collector of diode-coupled transistor 466 and to a terminal of current source circuitry 468 to receive a bias voltage VBIAS4A generated by bias voltage generator 460.

Base driver 410 has an input terminal coupled to base drive node 428 and has an output terminal. Base driver 412 has an input terminal coupled to base drive node 430 and has an output terminal. Capacitor 432 has a first terminal coupled to base drive node 428 and a second terminal coupled to output terminal 450. Capacitor 434 has a first terminal coupled to base drive node 430 and a second terminal coupled to output terminal 450. Transistor 438 has a first terminal (emitter) coupled to voltage supply terminal 424, a second terminal (collector) coupled to output terminal 450, and a control terminal (base) coupled to the output terminal of base driver 410. Transistor 440 has a first terminal (emitter) coupled to voltage supply terminal 426, a second terminal (collector) coupled to output terminal 450, and a control terminal (base) coupled to the output terminal of base driver 412.

Amplifier circuit 400 operates similarly to amplifier circuit 100 to produce an amplified output voltage VOUT responsive to a differential input voltage (VINP-VINM), with the transistors 446 and 448 redirecting error currents from the bases of transistors 442 and 444 to base drive nodes 428 and 430, resulting in an increased A_{OL}. Also, in example amplifier circuit 400, current source circuitry 420 and 422 produce fixed bias currents IBIAS4C and IBIAS4D at the emitters of transistors 448 and 446. In some examples, IBIAS4C and IBIAS4D have smaller magnitudes, e.g., are one sixth, the magnitudes of IBIAS4A and IBIAS4B to reduce contribution to signal noise and power dissipation. Current source circuits that produce fixed bias currents may also be referred to herein as fixed current source circuits or fixed current sources. Bias voltage generators 460 and 470 produce fixed bias voltages VBIAS4A and VBIAS4B at the bases of transistors 448 and 446.

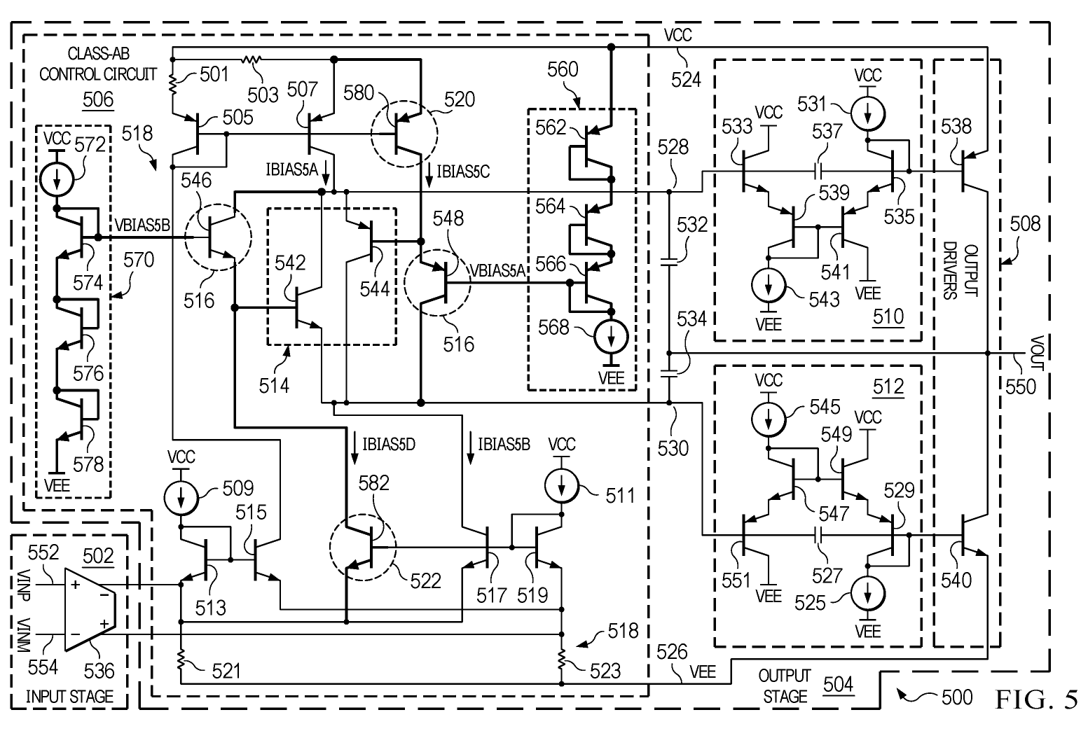

FIG. 5 is a circuit schematic illustrating another example amplifier circuit 500 including a control circuit with error current compensation. Amplifier circuit 500 includes an example input stage 502 coupled to an example output stage 504. Input stage 502 includes an example transconductance circuit 536. Output stage 504 includes an example control circuit 506, output drivers 508, a base driver 510, a base driver 512, a capacitor 532 and a capacitor 534. Control circuit 506 includes example control circuitry 514, example error current compensation circuitry 516, example current source circuitry 518, 520, and 522, and example bias voltage generators 560 and 570. Current source circuitry 518, 520, and 522 may also be referred to herein as bias current generators.

Control circuitry 514 includes transistors 542 and 544, which may also be referred to herein as control transistors. Error current compensation circuitry 516 includes transistors 546 and 548, which may also be referred to herein as compensation or recirculation transistors. Output drivers 508 include transistors 538 and 540, which may also be referred to as output transistors. Current source circuitry 518 includes diode-coupled transistor 505, transistor 507, diode-coupled transistor 513, transistor 515, transistor 517, diode-coupled transistor 519, resistors 501, 503, 521, and 523, and current source circuitry 509 and 511. Current source circuitry 520 includes a transistor 580. Current source circuitry 522 includes a transistor 582. Bias voltage generator 560 includes diode-coupled transistors 562, 564, and 566 and current source circuitry 568. Bias voltage generator 570 includes current source circuitry 572 and diode-coupled transistors 574, 576, and 578. Base driver 510 includes diode-coupled transistors 535 and 539, transistors 533 and 541, capacitor 537, and current source circuitry 531 and 543. Base driver 512 includes diode-coupled transistors 529 and 547, transistors 549 and 551, capacitor 527, and current source circuitry 525 and 545.

In example amplifier circuit 500, transistors 513, 515, 517, 519, 533, 535, 540, 542, 546, 547, 549, 574, 576, 578, and 582 are NPN BJTs, and transistors 505, 507, 529, 538, 539, 541, 544, 548, 551, 562, 564, 566, and 580 are PNP BJTs. In example amplifier circuit 500, diode-coupled transistors 505, 513, 519, 529, 535, 539, 547, 562, 564, 566, 574, 576, and 578 have a first terminal (collector) directly connected to a base of the transistor.

Further shown in FIG. 5 is a first voltage supply terminal 524 at which a first supply voltage VCC is provided, a second voltage supply terminal 526 at which a second supply voltage VEE is provided, a first base drive node 528, a second base drive node 530, a first input terminal 552 and a second input terminal 554 at which a differential voltage (VINP - VINM) is provided, and an output terminal 550 at which an output voltage VOUT is provided. Base drive node 528 represents a logical electrical point at which terminals of multiple elements are coupled to an input terminal of base driver 510. Base drive node 530 represents a logical electrical point at which terminals of multiple elements are coupled to an input terminal of base driver 512.

Transconductance circuit 536 has a first (positive) input coupled to input terminal 552, a second (negative) input coupled to input terminal 554, a first (positive) output, and a second (negative) output. As such, transconductance circuit 536 generates differential currents at its outputs, which have the same magnitude but different polarities. Transistors 505 and 507 are structured as a current mirror that inverts the polarity of one of these output currents so that common-mode currents that are proportional to the voltage difference between VINP and VINM are steered through control transistors 542 and 544. Current source circuitry 509, diode-coupled transistor 513, and resistor 521 are coupled in series between voltage supply terminal 524 and voltage supply terminal 526. Current source circuitry 511, diode-coupled transistor 519, and resistor 523 are coupled in series between voltage supply terminal 524 and voltage supply terminal 526. Resistor 501 and diode-coupled transistor 505 are coupled in series between voltage supply terminal 524 and a first terminal (collector) of transistor 515. A second terminal (emitter) of transistor 515 is coupled to a second terminal (emitter) of diode-coupled transistor 519, a terminal of resistor 523, and the positive output terminal of transconductance circuit 536. The control terminal (base) of transistor 515 is coupled to the collector and base of diode-coupled transistor 513 and to a terminal of current source circuitry 509. Resistor 503 and transistor 507 are coupled in series between voltage supply terminal 524 and base drive node 528. Transistor 517 has a first terminal (collector) coupled to base drive node 530 and a control terminal (base) coupled to the base and collector of diode-coupled transistor 519. Transistor 517 has a second terminal (emitter) coupled to a second terminal (emitter) of transistor 513, to a terminal of resistor 521, and to the negative output terminal of transconductance circuit 536. Current source circuitry 518 provides a bias current IBIAS5A at the collector of transistor 507 and a bias current IBIAS5B at the collector of transistor 517.

Transistor 542 has a first terminal (collector) coupled to base drive node 528, a second terminal (emitter) coupled to base drive node 530, and a control terminal (base). Transistor 544 has a first terminal (collector) coupled to base drive node 530, a second terminal (emitter) coupled to base drive node 528, and a control terminal (base). Transistor 546 has a first terminal (collector) coupled to base drive node 528, a second terminal (emitter) coupled to the base of transistor 542, and a control terminal (base). Transistor 548 has a first terminal (collector) coupled to base drive node 530, a second terminal (emitter) coupled to the base of transistor 544, and a control terminal (base).

Transistor 580 has a first terminal (collector) coupled to the base of transistor 544 and to the emitter of transistor 548, a second terminal (emitter) coupled to the emitter of transistor 507, and a control terminal (base) coupled to the base of transistor 507. Transistor 582 has a first terminal (collector) coupled to the base of transistor 542 and to the emitter of transistor 546, a second terminal (emitter) coupled to the emitter of transistor 517, and a control terminal (base) coupled to the base of transistor 517. Current source circuitry 520 provides a bias current IBIAS5C at the collector of transistor 580. Current source circuitry 522 provides a bias current IBIAS5D at the collector of transistor 582.

Current source circuitry 572 and diode-coupled transistors 574, 576, and 578 are coupled in series between voltage supply terminal 524 and voltage supply terminal 526. The base of transistor 546 is coupled to the base and collector of diode-coupled transistor 574 and to a terminal of current source circuitry 572 to receive a bias voltage VBIAS5B generated by bias voltage generator 570. Current source circuitry 568 and diode-coupled transistors 562, 564, and 566 are coupled in series between voltage supply terminal 524 and voltage supply terminal 526. The base of transistor 548 is coupled to the base and collector of diode-coupled transistor 566 and to a terminal of current source circuitry 568 to receive a bias voltage VBIAS5A generated by bias voltage generator 560.

In base driver 510, transistor 533, diode-coupled transistor 539, and current source circuitry 543 are coupled in series between voltage supply terminal 524 and voltage supply terminal 526. Current source circuitry 531, diode-coupled transistor 535, and transistor 541 are coupled in series between voltage supply terminal 524 and voltage supply terminal 526. A base of transistor 541 is coupled to a base and a collector of diode-coupled transistor 539 and to a terminal of current source circuitry 543. Capacitor 537 has a first terminal coupled to a base of transistor 533 and to base drive node 528. Capacitor 537 has a second terminal coupled to a base and a collector of diode-coupled transistor 535, to a terminal of current source circuitry 531, and to a control terminal (base) of transistor 538.

In base driver 512, transistor 549, diode-coupled transistor 529, and current source circuitry 525 are coupled in series between voltage supply terminal 524 and voltage supply terminal 526. Current source circuitry 545, diode-coupled transistor 547, and transistor 551 are coupled in series between voltage supply terminal 524 and voltage supply terminal 526. A base of transistor 549 is coupled to a base and a collector of diode-coupled transistor 547 and to a terminal of current source circuitry 545. Capacitor 527 has a first terminal coupled to a base of transistor 551 and to base drive node 530. Capacitor 527 has a second terminal coupled to a base and a collector of diode-coupled transistor 529, to a terminal of current source circuitry 525, and to a control terminal (base) of transistor 540.

Capacitor 532 has a first terminal coupled to base drive node 528 and a second terminal coupled to output terminal 550. Capacitor 534 has a first terminal coupled to base drive node 530 and a second terminal coupled to output terminal 550. Transistor 538 has a first terminal (emitter) coupled to voltage supply terminal 524 and a second terminal (collector) coupled to output terminal 550. Transistor 540 has a first terminal (emitter) coupled to voltage supply terminal 526 and a second terminal (collector) coupled to output terminal 550.

Amplifier circuit 500 operates similarly to amplifier circuit 100 to produce an amplified output voltage VOUT responsive to a differential input voltage (VINP-VINM), with the transistors 546 and 548 redirecting error currents from the bases of transistors 542 and 544 to base drive nodes 528 and 530, resulting in an increased A_{OL}. Also, bias voltage generators 560 and 570 produce fixed bias voltages VBIAS5A and VBIAS5B at the bases of transistors 548 and 546. However, in example amplifier circuit 500, current source circuitry 520 and 522 produce bias currents that are based on the bias currents IBIAS5A and IBIAS5B produced by current source circuitry 518. Namely, transistor 580 of current source circuitry 520 forms a current mirror with transistor 507 of current source circuitry 518, in which a fraction of the bias current IBIAS5A conducted through transistor 507 is conducted as bias current IBIAS5C through transistor 580. Similarly, transistor 582 of current source circuitry 522 forms a current mirror with transistor 517 of current source circuitry 518, in which a fraction of the bias current IBIAS5B conducted through transistor 517 is conducted as bias current IBIAS5D through transistor 582. In some examples, given an emitter area size 1x of transistors 507 and 517 (where x is an integer value), the emitter area size of transistors 580 and 582 is (1/n)*x, where n is 5 or greater. Thus, IBIAS5C is a proportion (in this example 1/n) of IBIAS5A, and IBIAS5D is a proportion (in this case 1/n) of IBIAS5B. This structure for producing IBIAS5C and IBIAS5D reduces amplifier noise and design complexity.

Also, the structure of base drivers 510 and 512 allows some additional efficiencies. For example, these two-rank base driver structures provide higher input impedance than other single-rank base driver designs, resulting in higher amplifier gain and linearity. Also, these structures have zero offset voltages between their inputs and outputs, unlike other base driver designs, allowing the minimum supply voltage for implementing amplifier circuit 500 to be as low as 2.7 V. In some examples, the structure of base drivers 510 and 512 can be implemented in amplifier circuits 100, 400, 600, and 700. Other base driver structures can be implemented, and which may provide similar efficiencies, for example base driver structures described in U. S. Patent Application No. 19/345,404, which is hereby incorporated by reference in its entirety.

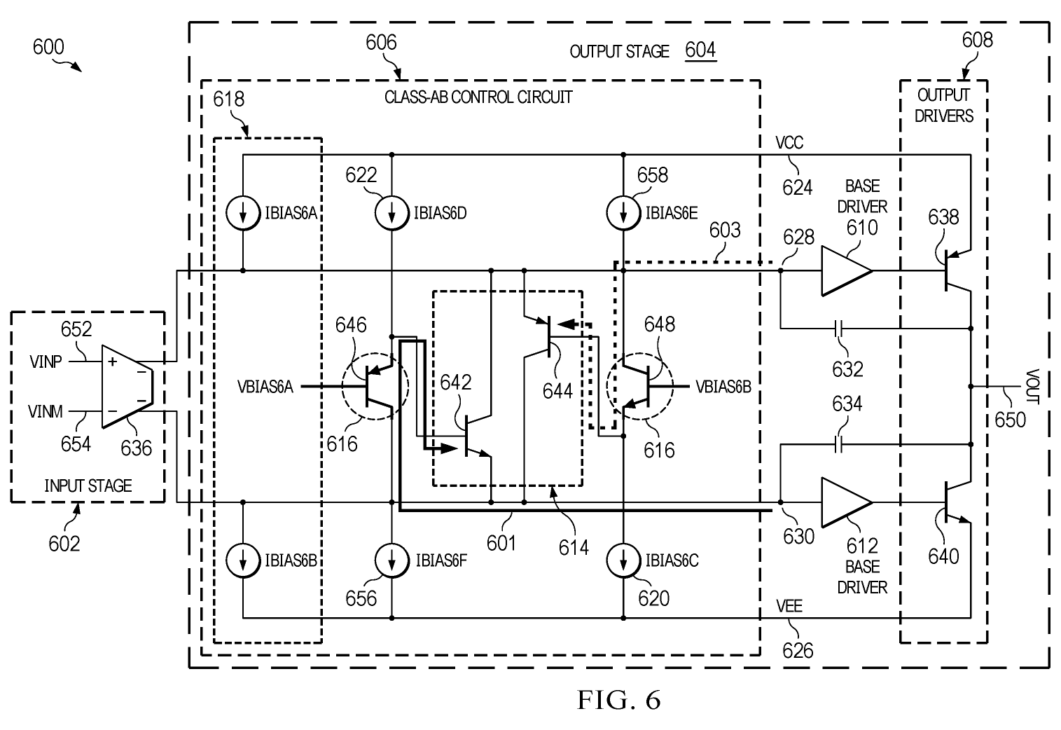

FIG. 6 is a circuit schematic illustrating another example amplifier circuit 600 including a control circuit with error current compensation. Amplifier circuit 600 includes an example input stage 602 coupled to an example output stage 604. Input stage 602 includes an example transconductance circuit 636. Output stage 604 includes an example control circuit 606, output drivers 608, a base driver 610, a base driver 612, a capacitor 632, and a capacitor 634. Control circuit 606 includes example control circuitry 614, example error current compensation circuitry 616, and example current source circuitry 618, 620, 622, 656, and 658. Current source circuitry 618, 620, 622, 656, and 658 may also be referred to herein as bias current generators. Control circuitry 614 includes transistors 642 and 644, which may also be referred to herein as control transistors. Error current compensation circuitry 616 includes transistors 646 and 648, which may also be referred to herein as compensation or recirculation transistors. Output drivers 608 include transistors 638 and 640, which may also be referred to as output transistors. In example amplifier circuit 600, transistors 640, 642, and 648 are NPN BJTs, and transistors 638, 644, and 646 are PNP BJTs.

Also shown in FIG. 6 is a first voltage supply terminal 624 at which a first supply voltage VCC is provided, a second voltage supply terminal 626 at which a second supply voltage VEE is provided, a first base drive node 628, a second base drive node 630, a first input terminal 652 and a second input terminal 654 at which a differential voltage (VINP - VINM) is provided, and an output terminal 650 at which an output voltage VOUT is provided. Base drive node 628 represents a logical electrical point at which terminals of multiple elements are coupled to an input terminal of base driver 610. Base drive node 630 represents a logical electrical point at which terminals of multiple elements are coupled to an input terminal of base driver 612.

Transconductance circuit 636 has a first (positive) input terminal coupled to input terminal 652, a second (negative) input terminal coupled to input terminal 654, a first (negative) output terminal coupled to base drive node 628, and a second (negative) output terminal coupled to base drive node 630. Current source circuitry 618 has a first terminal coupled to voltage supply terminal 624, a second terminal coupled to base drive node 628, a third terminal coupled to base drive node 630, and a fourth terminal coupled to voltage supply terminal 626. Current source circuitry 618 provides a bias current IBIAS6A and a bias current IBIAS6B.

Transistor 642 has a first terminal (collector) coupled to base drive node 628, a second terminal (emitter) coupled to base drive node 630, and a control terminal (base). Transistor 644 has a first terminal (collector) coupled to base drive node 630, a second terminal (emitter) coupled to base drive node 628, and a control terminal (base). Transistor 646 has a first terminal (collector) coupled to base drive node 630, a second terminal (emitter) coupled to the base of transistor 642, and a control terminal (base) that receives a bias voltage VBIAS6A. Transistor 648 has a first terminal (collector) coupled to base drive node 628, a second terminal (emitter) coupled to the base of transistor 644, and a control terminal (base) that receives a bias voltage VBIAS6B.

Current source circuitry 620 has a first terminal coupled to voltage supply terminal 626 and a second terminal coupled to the base of transistor 644 and to the emitter of transistor 648. Current source circuitry 622 has a first terminal coupled to voltage supply terminal 624 and a second terminal coupled to the base of transistor 642 and to the emitter of transistor 646. Current source circuitry 656 is coupled between base drive node 630 and voltage supply terminal 626. Current source circuitry 658 is coupled between base drive node 628 and voltage supply terminal 624. Current source circuitry 620 provides a bias current IBIAS6C. Current source circuitry 622 provides a bias current IBIAS6D. Current source circuitry 658 provides a bias current IBIAS6E. Current source circuitry 656 provides a bias current IBIAS6F.

Base driver 610 has an input terminal coupled to base drive node 628 and has an output terminal. Base driver 612 has an input terminal coupled to base drive node 630 and has an output terminal. Capacitor 632 has a first terminal coupled to base drive node 628 and a second terminal coupled to output terminal 650. Capacitor 634 has a first terminal coupled to base drive node 630 and a second terminal coupled to output terminal 650. Transistor 638 has a first terminal (collector) coupled to output terminal 650, a second terminal (emitter) coupled to voltage supply terminal 624, and a control terminal (base) coupled to the output terminal of base driver 610. Transistor 640 has a first terminal (collector) coupled to output terminal 650, a second terminal (emitter) coupled to voltage supply terminal 626, and a control terminal (base) coupled to the output terminal of base driver 612.

Amplifier circuit 600 operates similarly to amplifier circuit 100 to produce an amplified output voltage VOUT responsive to a differential input voltage (VINP-VINM), with the transistors 646 and 648 redirecting error currents from the bases of transistors 642 and 644 to base drive nodes 628 and 630, resulting in an increased A_{OL}. However, in amplifier circuit 600, two additional current source circuits may be included, which supply IBIAS6E and IBIAS6F, to provide adequate quiescent current to meet slew requirements of the amplifier circuit 600. Also, in amplifier circuit 600, recirculation transistors of error current compensation circuitry 616 are of a complementary type from the control transistors of control circuitry 614. Particularly, control transistor 642 is an NPN BJT and recirculation transistor 646 is a PNP BJT. Also, control transistor 644 is a PNP BJT and recirculation transistor 648 is a NPN BJT. Whereas, in amplifier circuit 100, recirculation transistors of error current compensation circuitry 116 are of a same type as the control transistors of control circuitry 114. Particularly, control transistor 142 is an NPN BJT and recirculation transistor 146 is a NPN BJT. Also, control transistor 144 is a PNP BJT and recirculation transistor 148 is a PNP BJT. In operation, transistor 646 is coupled so that base current drawn by transistor 642 produces a corresponding conduction current between the emitter and the collector of transistor 646. Rather than allowing this current to be dissipated locally within the control circuit 606, transistor 646 redirects the recovered current into the signal path coupled to base drive node 630, as shown by solid line 601. Similarly, transistor 648 is coupled so that base current drawn by transistor 644 causes conduction from the emitter to the collector of transistor 648, which is redirected to base drive node 628, as shown by dashed line 603.

Using complementary-type recirculation transistors to convey error currents at the bases of the control transistors reduces headroom requirements, enabling operation of amplifier circuit 600 on a lower supply voltage as compared to amplifier circuits 100, 400, and 500. For example, amplifier circuit 100 can operate on a minimum supply voltage of the VBE of transistor 140 plus the VBE of transistor 142 (or 144) plus the VCE of transistor 146 (or 148) plus the VBE of transistor 138, which may be around 2.7 V. Whereas, amplifier circuit 600 can operate on a minimum supply voltage of the VBE of transistor 640 plus the VCE of transistor 642 (or 644) plus the VBE of transistor 638, which may be around 2.0 V.

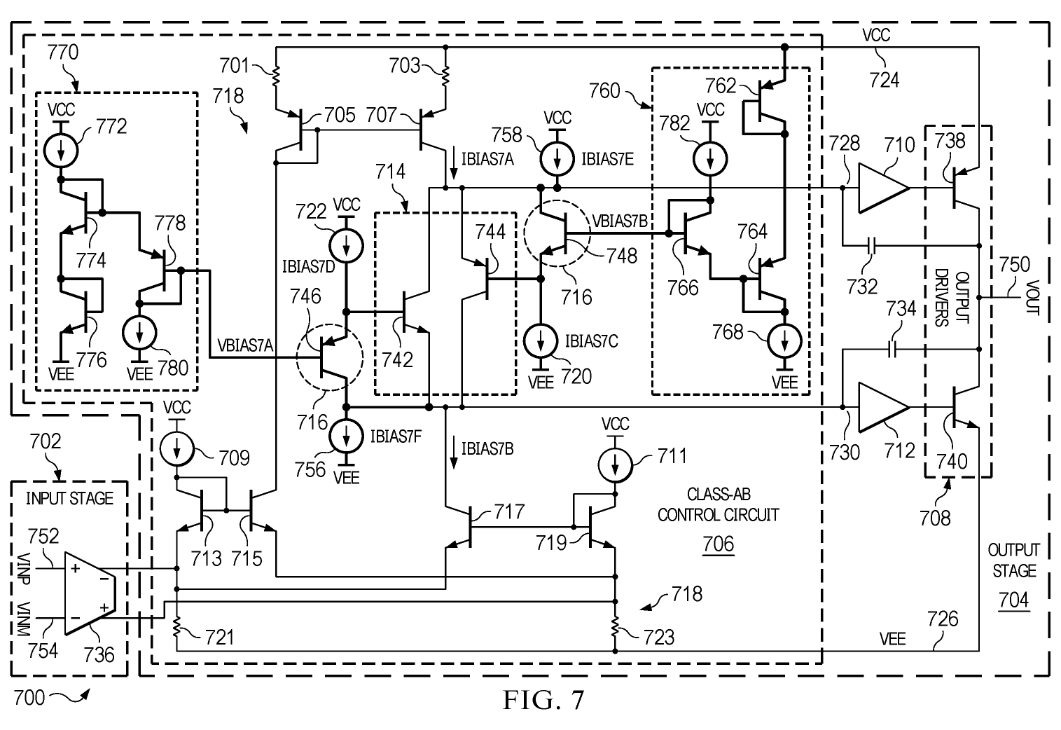

FIG. 7 is a circuit schematic illustrating another example amplifier circuit 700 including a control circuit with error current compensation. Amplifier circuit 700 includes an example input stage 702 coupled to an example output stage 704. Input stage 702 includes an example transconductance circuit 736. Output stage 704 includes an example control circuit 706, output drivers 708, a base driver 710, a base driver 712, a capacitor 732, and a capacitor 734. Control circuit 706 includes example control circuitry 714, example error current compensation circuitry 716, example current source circuitry 718, 720, 722, 756, and 758, and example bias voltage generators 760 and 770. Current source circuitry 718, 720, and 722 may also be referred to herein as bias current generators.

Control circuitry 714 includes transistors 742 and 744, which may also be referred to herein as control transistors. Error current compensation circuitry 716 includes transistors 746 and 748, which may also be referred to herein as compensation or recirculation transistors. Output drivers 708 include transistors 738 and 740, which may also be referred to as output transistors. Current source circuitry 718 includes diode-coupled transistor 705, transistor 707, diode-coupled transistor 713, transistor 715, transistor 717, diode-coupled transistor 719, resistors 701, 703, 721, and 723, and current source circuitry 709 and 711. Bias voltage generator 760 includes diode-coupled transistors 762, 764, and 766 and current source circuitry 768 and 782. Bias voltage generator 770 includes current source circuitry 772 and 780 and diode-coupled transistors 774, 776, and 778.

In example amplifier circuit 700, transistors 713, 715, 717, 719, 740, 742, 748, 766, 774, and 776 are NPN BJTs, and transistors 705, 707, 738, 744, 746, 762, 764, and 778 are PNP BJTs. In example amplifier circuit 700, diode-coupled transistors 705, 713, 719, 762, 764, 766, 774, 776, and 778 have a first terminal (collector) directly connected to a base of the transistor.

Further shown in FIG. 7 is a first voltage supply terminal at which a first supply voltage VCC is provided, a second voltage supply terminal at which a second supply voltage VEE is provided, a first base drive node 728, a second base drive node 730, a first input terminal 752 and a second input terminal 754 at which a differential voltage (VINP - VINM) is provided, and an output terminal 750 at which an output voltage VOUT is provided. Base drive node 728 represents a logical electrical point at which terminals of multiple elements are coupled to an input terminal of base driver 710. Base drive node 730 represents a logical electrical point at which terminals of multiple elements are coupled to an input terminal of base driver 712.

Transconductance circuit 736 has a first (positive) input coupled to input terminal 752, a second (negative) input coupled to input terminal 754, a first (positive) output, and a second (negative) output. As such, transconductance circuit 736 generates differential currents at its outputs, which have the same magnitude but different polarities. Transistors 705 and 707 are structured as a current mirror that inverts the polarity of one of these output currents so that common-mode currents that are proportional to the voltage difference between VINP and VINM are steered through control transistors 742 and 744. Current source circuitry 709, diode-coupled transistor 713, and resistor 721 are coupled in series between voltage supply terminal 724 and voltage supply terminal 726. Current source circuitry 711, diode-coupled transistor 719, and resistor 723 are coupled in series between voltage supply terminal 724 and voltage supply terminal 726. Resistor 701 and diode-coupled transistor 705 are coupled in series between voltage supply terminal 724 and a first terminal (collector) of transistor 715. A second terminal (emitter) of transistor 715 is coupled to a second terminal (emitter) of diode-coupled transistor 719, a terminal of resistor 723, and the positive output terminal of transconductance circuit 736. The control terminal (base) of transistor 715 is coupled to the collector and base of diode-coupled transistor 713 and to a terminal of current source circuitry 709. Resistor 703 and transistor 707 are coupled in series between voltage supply terminal 724 and base drive node 728. Transistor 717 has a first terminal (collector) coupled to base drive node 730 and a control terminal (base) coupled to the base and collector of diode-coupled transistor 719. Transistor 717 has a second terminal (emitter) coupled to a second terminal (emitter) of transistor 713, to a terminal of resistor 721, and to the negative output terminal of transconductance circuit 736. Current source circuitry 718 provides a bias current IBIAS7A at the collector of transistor 707 and a bias current IBIAS7B at the collector of transistor 717.

Transistor 742 has a first terminal (collector) coupled to base drive node 728, a second terminal (emitter) coupled to base drive node 730, and a control terminal (base). Transistor 744 has a first terminal (collector) coupled to base drive node 730, a second terminal (emitter) coupled to base drive node 728, and a control terminal (base). Transistor 746 has a first terminal (collector) coupled to base drive node 730, a second terminal (emitter) coupled to the base of transistor 742, and a control terminal (base). Transistor 748 has a first terminal (collector) coupled to base drive node 728, a second terminal (emitter) coupled to the base of transistor 744, and a control terminal (base).

Current source circuitry 720 has a first terminal coupled to voltage supply terminal 726 and a second terminal coupled to the base of transistor 744 and to the emitter of transistor 748. Current source circuitry 722 has a first terminal coupled to voltage supply terminal 724 and a second terminal coupled to the base of transistor 742 and to the emitter of transistor 746. Current source circuitry 756 is coupled between the collector of transistor 746 and the voltage supply terminal 726. Current source circuitry 758 is coupled between the collector of transistor 748 and the voltage supply terminal 724. Current source circuitry 720 provides a bias current IBIAS7C. Current source circuitry 722 provides a bias current IBIAS7D. Current source circuitry 758 provides a bias current IBIAS7E. Current source circuitry 756 provides a bias current IBIAS7F.

Current source circuitry 772 and diode-coupled transistors 774 and 776 are coupled in series between voltage supply terminal 724 and voltage supply terminal 726. Diode-coupled transistor 778 and current source circuit 780 are coupled in series between the base of diode-coupled transistor 774 and voltage supply terminal 726. The base of transistor 746 is coupled to the base and collector of diode-coupled transistor 778 and to a terminal of current source circuitry 780 to receive a bias voltage VBIAS7A generated by bias voltage generator 770. Current source circuitry 768 and diode-coupled transistors 762 and 764 are coupled in series between voltage supply terminal 724 and voltage supply terminal 726. Current source circuitry 782 and diode-coupled transistor 766 are coupled in series between voltage supply terminal 724 and the base of diode-coupled transistor 764. The base of transistor 748 is coupled to the base and collector of diode-coupled transistor 766 and to a terminal of current source circuitry 782 to receive a bias voltage VBIAS7B generated by bias voltage generator 760.

Base driver 710 has an input terminal coupled to base drive node 728 and has an output terminal. Base driver 712 has an input terminal coupled to base drive node 730 and has an output terminal. Capacitor 732 has a first terminal coupled to base drive node 728 and a second terminal coupled to output terminal 750. Capacitor 734 has a first terminal coupled to base drive node 730 and a second terminal coupled to output terminal 750. Transistor 738 has a first terminal (emitter) coupled to voltage supply terminal 724, a second terminal (collector) coupled to output terminal 750, and a control terminal (base) coupled to the output terminal of base driver 710. Transistor 740 has a first terminal (emitter) coupled to voltage supply terminal 726, a second terminal (collector) coupled to output terminal 750, and a control terminal (base) coupled to the output terminal of base driver 712.

Amplifier circuit 700 operates similarly to amplifier circuit 100 to produce an amplified output voltage VOUT responsive to a differential input voltage (VINP-VINM), with the transistors 746 and 748 redirecting lost currents from the bases of transistors 742 and 744 to base drive nodes 728 and 730, resulting in an increased A_{OL}. However, amplifier circuit 700 uses the complementary-type recirculation transistors like amplifier circuit 600, which enables the lower operating supply voltage as compared to amplifier circuit 100.

Various examples of the description can be described as follows.
Example 1. A circuit includes a first transistor having a collector, an emitter, and a base, a second transistor having a collector coupled to the emitter of the first transistor, an emitter coupled to the collector of the first transistor, and a base, a third transistor having a first terminal coupled to the base of the first transistor and having a second terminal coupled to the collector of the first transistor and to the emitter of the second transistor, and a fourth transistor having a first terminal coupled to the base of the second transistor and having a second terminal coupled to the collector of the second transistor and to the emitter of the first transistor.
Example 2. A circuit according to example 1, wherein the first terminals of the third and fourth transistors are emitters, and the second terminals of the third and fourth transistors are collectors.
Example 3. A circuit according to any of examples 1 and 2, wherein the first and third transistors are NPN bipolar junction transistors (BJTs), and the second and fourth transistors are PNP BJTs.
Example 4. A circuit according to and of examples 1–3, further including a first current source coupled to the first terminal of the third transistor and a second current source coupled to the first terminal of the fourth transistor.
Example 5. A circuit according to example 4, wherein the first and second current sources are fixed current sources.
Example 6. A circuit according to example 4, wherein the first current source produces a first current that is a fraction of a first bias current at the emitter of the first transistor and the collector of the second transistor, and the second current source produces a second current that is a fraction of a second bias current at the collector of the first transistor and the emitter of the second transistor.
Example 7. A circuit according to example 4, further including a bias current generator having a fifth transistor coupled to the emitter of the first transistor and the collector of the second transistor and a sixth transistor coupled to the collector of the first transistor and the emitter of the second transistor, wherein the first current source includes a seventh transistor forming a first current mirror with the fifth transistor, and the second current source includes an eighth transistor forming a second current mirror with the sixth transistor.
Example 8. A circuit according to example 7, wherein the bias current generator produces a first bias current in the fifth transistor and a second bias current in the sixth transistor, the first current source produces a first current in the seventh transistor that is a fraction of the first bias current, and the second current source produces a second current in the eighth transistor that is a fraction of the second bias current.
Example 9. A circuit according to any of the preceding examples, further including a first driver circuit having an input terminal coupled to the collectors of the first and third transistors and to the emitter of the second transistor and having an output terminal, a second driver circuit having an input terminal coupled to the collectors of the second and fourth transistors and to the emitter of the first transistor and having an output terminal, and fifth and sixth transistors coupled in series between a first voltage supply terminal and a second voltage supply terminal, the fifth transistor having a control terminal coupled to the output terminal of the first driver circuit and the sixth transistor having a control terminal coupled to the output terminal of the second driver circuit.
Example 10. A circuit includes a first transistor having a collector, an emitter, and a base, a second transistor having a collector coupled to the emitter of the first transistor, an emitter coupled to the collector of the first transistor, and a base, a third transistor having a first terminal coupled to the base of the first transistor and having a second terminal coupled to the emitter of the first transistor and to the collector of the second transistor, and a fourth transistor having a first terminal coupled to the base of the second transistor and having a second terminal coupled to the emitter of the second transistor and to the collector of the first transistor.
Example 11. A circuit according to example 10, wherein the first terminals of the third and fourth transistors are emitters, and the second terminals of the third and fourth transistors are collectors.
Example 12. A circuit according to any of examples 10 and 11, wherein the second and third transistors are NPN bipolar junction transistors (BJTs), and the first and fourth transistors are PNP BJTs.
Example 13. A circuit according to any of examples 10–12, further including a first current source coupled to the first terminal of the third transistor, a second current source coupled to the first terminal of the fourth transistor, a third current source coupled to the second terminal of the third transistor, and a fourth current source coupled to the second terminal of the fourth transistor.
Example 14. A circuit according to any of examples 10–13, further including a first driver circuit having an input terminal coupled to the collectors of the second and third transistors and to the emitter of the first transistor and having an output terminal, a second driver circuit having an input terminal coupled to the collectors of the first and fourth transistors and to the emitter of the second transistor and having an output terminal, and fifth and sixth transistors coupled in series between a first voltage supply terminal and a second voltage supply terminal, the fifth transistor having a control terminal coupled to the output terminal of the first driver circuit and the sixth transistor having a control terminal coupled to the output terminal of the second driver circuit.
Example 15. A circuit includes control circuitry including a first transistor coupled in parallel to a second transistor, the first and second transistors having respective control terminals, wherein the first transistor produces a first current based on an input voltage and the second transistor produces a second current based on the input voltage, and error current compensation circuitry including a third transistor having a first terminal coupled to the control terminal of the first transistor and a second terminal coupled to first terminals of the first and second transistors, wherein the third transistor redirects a third current generated at the control terminal of the first transistor, and a fourth transistor having a first terminal coupled to the control terminal of the second transistor and a second terminal coupled to second terminals of the first and second transistors, wherein the fourth transistor redirects a fourth current generated at the control terminal of the second transistor.
Example 16. A circuit according to example 15, wherein the error current compensation circuitry includes a first current source coupled to the first terminal of the third transistor and a second current source coupled to the first terminal of the fourth transistor.
Example 17. A circuit according to example 16, wherein the first and second current sources are fixed current sources.
Example 18. A circuit according to example 16, wherein the control circuitry includes a third current source including a fifth transistor coupled to the first and second transistors and a sixth transistor coupled to the first and second transistors, wherein the first current source includes a seventh transistor forming a first current mirror with the fifth transistor, and the second current source includes an eighth transistor forming a second current mirror with the sixth transistor.
Example 19. A circuit according to example 16, further including a third current source coupled to the second terminal of the third transistor and a fourth current source coupled to the second terminal of the fourth transistor.
Example 20. A circuit according to any of examples 15-18, wherein the first and third transistors are NPN bipolar junction transistors (BJTs), and the second and fourth transistors are PNP BJTs.
Example 21. A circuit according to any of examples 15–17 and 20, wherein the second and third transistors are NPN bipolar junction transistors (BJTs), and the first and fourth transistors are PNP BJTs.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” or “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor components. Also, unless specifically stated to the contrary, an “input” referred to on its own is used interchangeably with “input terminal” and “output” referred to on its own is used interchangeably with “output terminal.”

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be in depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/- 10 percent of that parameter or, if the parameter is zero, a reasonable range of values around zero.

Modifications are possible in the described examples, and other examples are possible, within the scope of the claims.

What is claimed is:

1. A circuit comprising:
a first transistor having a collector, an emitter, and a base;
a second transistor having a collector coupled to the emitter of the first transistor, an emitter coupled to the collector of the first transistor, and a base;
a third transistor having first terminal coupled to the base of the first transistor and having second terminal coupled to the collector of the first transistor and to the emitter of the second transistor; and
a fourth transistor having first terminal coupled to the base of the second transistor and having a second terminal coupled to the collector of the second transistor and to the emitter of the first transistor.

2. The circuit of claim 1, wherein the first terminals of the third and fourth transistors are emitters, and the second terminals of the third and fourth transistors are collectors.

3. The circuit of claim 2, wherein the first and third transistors are NPN bipolar junction transistors (BJTs), and the second and fourth transistors are PNP BJTs.

4. The circuit of claim 1 further comprising:
a first current source coupled to the first terminal of the third transistor; and
a second current source coupled to the first terminal of the fourth transistor.

5. The circuit of claim 4, wherein the first and second current sources are fixed current sources.

6. The circuit of claim 4, wherein the first current source is configurable to produce a first current that is a fraction of a first bias current at the emitter of the first transistor and the collector of the second transistor, and the second current source is configurable to produce a second current that is a fraction of a second bias current at the collector of the first transistor and the emitter of the second transistor.

7. The circuit of claim 4, further including a bias current generator having a fifth transistor coupled to the emitter of the first transistor and the collector of the second transistor and a sixth transistor coupled to the collector of the first transistor and the emitter of the second transistor, wherein the first current source includes a seventh transistor forming a first current mirror with the fifth transistor, and the second current source includes an eighth transistor forming a second current mirror with the sixth transistor.

8. The circuit of claim 7, wherein the bias current generator is configurable to produce a first bias current in the fifth transistor and a second bias current in the sixth transistor, the first current source is configurable to produce a first current in the seventh transistor that is a fraction of the first bias current, and the second current source is configurable to produce a second current in the eight transistor that is a fraction of the second bias current.

9. The circuit of claim 1, further comprising:
a first driver circuit having an input terminal coupled to the collectors of the first and third transistors and to the emitter of the second transistor, and having an output terminal;
a second driver circuit having an input terminal coupled to the collectors of the second and fourth transistors and to the emitter of the first transistor, and having an output terminal;
fifth and sixth transistors coupled in series between a first voltage supply terminal and a second voltage supply terminal, the fifth transistor having a control terminal coupled to the output terminal of the first driver circuit, the sixth transistor having a control terminal coupled to the output terminal of the second driver circuit.

10. A circuit comprising:
a first transistor having a collector, an emitter, and a base;
a second transistor having a collector coupled to the emitter of the first transistor, an emitter coupled to the collector of the first transistor, and a base;
a third transistor having first terminal coupled to the base of the first transistor and having second terminal coupled to the emitter of the first transistor and to the collector of the second transistor; and
a fourth transistor having first terminal coupled to the base of the second transistor and having a second terminal coupled to the emitter of the second transistor and to the collector of the first transistor.

11. The circuit of claim 10, wherein the first terminals of the third and fourth transistors are emitters, and the second terminals of the third and fourth transistors are collectors.

12. The circuit of claim 11, wherein the second and third transistors are NPN bipolar junction transistors (BJTs), and the first and fourth transistors are PNP BJTs.

13. The circuit of claim 10, further comprising:
a first current source coupled to the first terminal of the third transistor;
a second current source coupled to the first terminal of the fourth transistor;
a third current source coupled to the second terminal of the third transistor; and
a fourth current source coupled to the second terminal of the fourth transistor.

14. The circuit of claim 10, further comprising:
a first driver circuit having an input terminal coupled to the collectors of the second and third transistors and to the emitter of the first transistor, and having an output terminal;
a second driver circuit having an input terminal coupled to the collectors of the first and fourth transistors and to the emitter of the second transistor, and having an output terminal;
fifth and sixth transistors coupled in series between a first voltage supply terminal and a second voltage supply terminal, the fifth transistor having a control terminal coupled to the output terminal of the first driver circuit, the sixth transistor having a control terminal coupled to the output terminal of the second driver circuit.

15. A circuit comprising:
control circuitry including a first transistor coupled in parallel to a second transistor, the first and second transistors having respective control terminals, wherein the first transistor is configurable to produce a first current based on an input voltage, and the second transistor is configurable to produce a second current based on the input voltage; and
error current compensation circuitry including:
a third transistor having a first terminal coupled to the control terminal of the first transistor and a second terminal coupled to first terminals of the first and second transistors, wherein the third transistor is configurable to redirect a third current generated at the control terminal of the first transistor; and
a fourth transistor having a first terminal coupled to the control terminal of the second transistor and a second terminal coupled to second terminals of the first and second transistors, wherein the fourth transistor is configurable to redirect a fourth current generated at the control terminal of the second transistor.

16. The circuit of claim 15, wherein the error current compensation circuit includes:
a first current source coupled to the first terminal of the third transistor; and
a second current source coupled to the first terminal of the fourth transistor.

17. The circuit of claim 16, wherein the first and second current sources are fixed current sources.

18. The circuit of claim 16, wherein the control circuit includes a third current source including a fifth transistor coupled to the first and second transistors and a sixth transistor coupled to first and second transistors, wherein the first current source includes a seventh transistor forming a first current mirror with the fifth transistor, and the second current source includes an eighth transistor forming a second current mirror with the sixth transistor.

19. The circuit of claim 16, further comprising:
a third current source coupled to the second terminal of the third transistor; and
a fourth current source coupled to the second terminal of the fourth transistor.

20. The circuit of claim 15, wherein the first and third transistors are NPN bipolar junction transistors (BJTs), and the second and fourth transistors are PNP BJTs.

21. The circuit of claim 15, wherein the second and third transistors are NPN bipolar junction transistors (BJTs), and the first and fourth transistors are PNP BJTs.
